(19) United States
(12) Patent Application Publication
(10) Pub. No.: US 2009/0002625 A1
(43) Pub. Date: Jan. 1, 2009

(54) DISPLAY APPARATUSES WITH JOINING LAYERS AND BUFFER LAYERS, AND METHOD OF FABRICATING THE SAME

(76) Inventors: Won-Hoe Koo, Suwon-si (KR); Hoon Kim, Hwaseong-si (KR); Jin-Koo Chung, Suwon-si (KR); Jung-Mi Choi, Yongin-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/142,685

(22) Filed: Jun. 19, 2008

(30) Foreign Application Priority Data
Jun. 22, 2007 (KR) 10-2007-0061692

(51) Int. Cl. G02F 1/1333; H01L 21/30

(52) U.S. Cl. 349/158; 438/455; 257/E21.237

(57) ABSTRACT

A display apparatus includes a first substrate, a second substrate facing the first substrate, a joining layer interposed between the first and second substrates, and a buffer layer interposed between the joining layer and at least one of the first and second substrates. The buffer layer has a lower heat conductivity than the joining layer to protect the first or second substrate from the heat generated in the joining layer during fabrication.

### CROSS-REFERENCE TO RELATED APPLICATION

This application claims priority of South Korean Patent Application No. 2007-61692 filed on Jun. 22, 2007, incorporated herein by reference.

### BACKGROUND OF THE INVENTION

1. Field of the Invention

The present invention relates to display apparatuses and their fabrication methods. Some embodiments provide display apparatuses that can be manufactured at a reduced cost.

2. Description of the Related Art

A display apparatus uses electrical signals to display an image. Various display apparatuses have been developed, and flat panel displays have been widely used in recent times. For example, liquid crystal displays, plasma displays, and electroluminance displays have been used for computer monitors, digital television sets, and cellular telephones.

A flat panel display includes an array substrate on which metal lines are formed to conduct electrical signals, and another substrate opposite to the array substrate. An optical layer is disposed between the array substrate and the opposite substrate. In a liquid crystal display, the optical layer is a layer of liquid crystal, and in an electroluminance display the optical layer is a light-emitting layer including an organic thin film.

The array substrate and the opposite substrate are bonded together, and the bonding forms a seal that protects the optical layer from moisture and other contaminants that could cause degradation of the displayed image.

It is desirable to develop display apparatuses and their manufacturing process that would reduce the manufacturing costs associated with the bonding process.

### SUMMARY

This section summarizes some features of the invention. Other features are described in subsequent sections. The invention is defined by the appended claims.

The present invention provides display apparatuses and methods of fabrication of display apparatuses. Manufacturing costs are reduced in some embodiments.

In some embodiments of the present invention, a display apparatus includes a first substrate on which pixel areas are defined, a second substrate facing the first substrate, a joining layer interposed between the first and second substrates, to bond the first and second substrates to each other, and a buffer layer interposed between the joining layer and at least one of the first and second substrates, the buffer layer having lower heat conductivity than the joining layer.

In some embodiments, each of the joining layer and the buffer layer includes a joining agent and a filling agent. In some embodiments, the weight concentration of the filling agent in the joining layer is in a range from about 10% to about 30%, and the weight concentration of the filling agent in the buffer layer is in a range from about 50% to about 90%.

In some embodiments of the present invention, a method of fabricating a display apparatus includes providing a first substrate on which pixel areas are defined, and a second substrate; forming a buffer layer on at least one of the first and second substrates; forming a joining layer on the buffer layer, the joining layer having a higher heat conductivity than the buffer layer; bonding the first and second substrates to each other, with the buffer layer and the joining layer being between the first and second substrates.

In some embodiments, the lower heat conductivity of the buffer layer serves to protect the first or second substrate from the heat generated in the joining layer during fabrication.

### BRIEF DESCRIPTION OF THE DRAWINGS

FIG. 1 is a cross-sectional view showing an exemplary embodiment of a display apparatus according to the present invention;

FIG. 2 is a perspective view showing a substrate of the apparatus of FIG. 1;

FIG. 3A is an exploded perspective view showing an exemplary embodiment of an inner configuration of the display apparatus of FIG. 1;

FIG. 3B is an exploded perspective view showing another exemplary embodiment of an inner configuration of the display apparatus of FIG. 1;

FIGS. 4A and 4B are cross-sectional views showing a joining layer and a buffer layer of FIG. 1, respectively;

FIG. 5 is a cross-sectional view showing another exemplary embodiment of a display apparatus according to the present invention;

FIG. 6 is a cross-sectional view showing another exemplary embodiment of a display apparatus according to the present invention;

FIGS. 7A to 7F illustrate a display apparatus at different stages of fabrication according to some embodiments of the present invention; and

FIGS. 8A to 8D are enlarged views showing the respective portions ‘A’, ‘B’, ‘C’, and ‘D’ of FIGS. 7A to 7D.

### DESCRIPTION OF SOME EMBODIMENTS

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated items.

It will be understood that the terms like “first”, “second”, etc. are merely reference labels used to distinguish one element from another.

Spatially relative terms, such as “beneath”, “below”, “lower”, “above”, “upper” and the like, may be used herein to describe relative spacial positions of elements in a combination of elements for a given spacial orientation of the combination. The invention is not limited to a particular spacial orientation however, and specific orientations are illustrated merely for ease of description and not to limit the invention.

Some embodiments of the present invention will now be explained in detail with reference to the accompanying drawings.

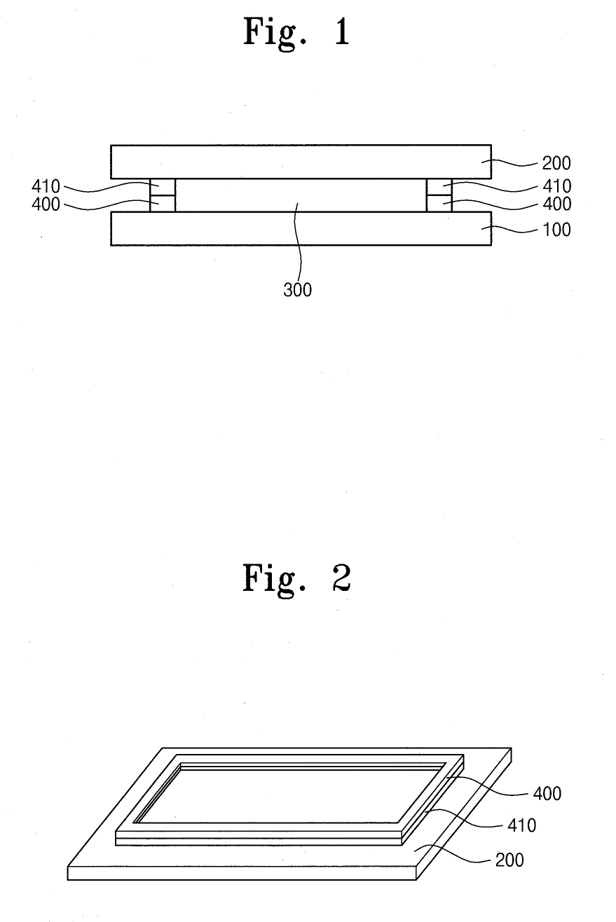

FIG. 1 is a cross-sectional view of an exemplary embodiment of a display apparatus according to the present invention, and FIG. 2 is a perspective view showing a second substrate 200 of FIG. 1.

The display apparatus includes a first substrate 100, the second substrate 200 facing the first substrate 100, an optical layer 300, a joining layer 400, and a buffer layer 410. The first substrate 100 is below the second substrate 200 in the view of FIG. 1. The optical layer 300 is disposed between the first and second substrates 100 and 200, and the joining layer 400 and the buffer layer 410 are also disposed between the first and second substrates 100 and 200. The optical layer 300 is surrounded by the first and second substrates 100 and 200, the joining layer 400, and the buffer layer 410.

The optical layer 300 may include different materials depending on the type of the display apparatus. For instance, if the display apparatus is a liquid crystal display, then the optical layer 300 includes a liquid crystal layer. If the display apparatus is an electroluminance display, then the optical layer 300 includes a light emitting layer having organic materials. Further, if the display apparatus is a plasma display, then the optical layer 300 may include a discharge gas, such as neon, xenon, etc.

Referring to FIG. 2, the buffer layer 410 is formed along the periphery of the second substrate 200 in a closed-loop pattern. The joining layer 400 is positioned on the buffer layer 410. The joining layer 400 and the buffer layer 410 are overlapped with each other in a plan view, and the buffer layer 410 and the joining layer 400 are substantially placed at the same position in a plan view.

The buffer layer 410 has lower heat conductivity than the joining layer 400. The buffer layer 410 protects the second substrate 200 from the heat generated during fabrication of the display apparatus. The buffer layer 410 and the joining layer 400 are described in detail below in connection with a method of fabricating the display apparatus.

In some alternative embodiments, the buffer layer 410 is formed on the first substrate 100 above the joining layer 400 in the view of FIG. 2, and hence below the joining layer 400 in the view of FIG. 1. In this case, the buffer layer 410 protects the first substrate 100 from the heat generated during the fabrication.

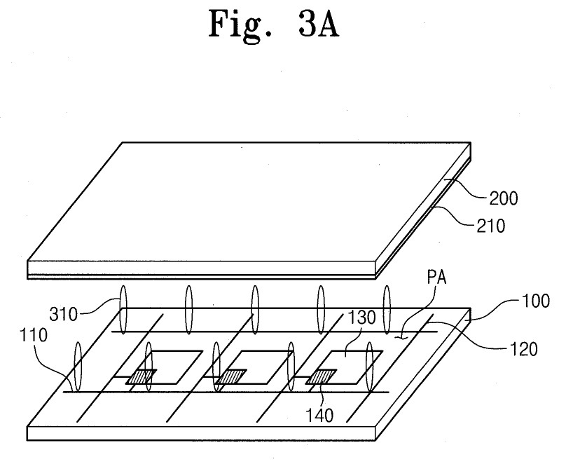

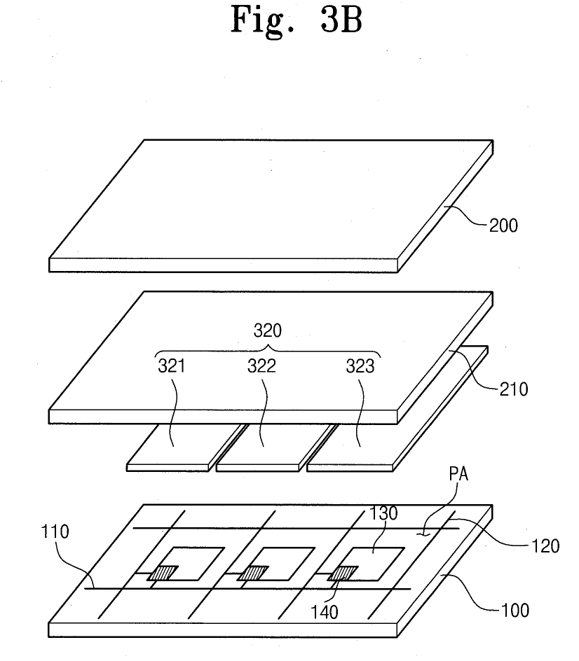

FIG. 3A is an exploded perspective view showing an exemplary inner configuration of the display apparatus of FIG. 1, and FIG. 3B is an exploded perspective view showing another possible inner configuration for the display apparatus of FIG. 1.

Referring to FIG. 3A, a plurality of metal lines are formed on the first substrate 100. The metal lines include first lines 110 and second lines 120. The first and second lines 110 and 120 cross over each other and are electrically insulated from each other to define a plurality of pixel areas. The first lines 110 extend essentially in the same direction which is perpendicular to the direction of the second lines 120. The pixel areas are arranged in a matrix. The first substrate 100 serves as an array substrate on which the pixel areas are defined.

Each pixel area includes a first electrode 130 and a thin film transistor 140. The thin film transistor 140 includes a control electrode connected to the corresponding first line 110, an input electrode connected to the corresponding second line 120, and an output electrode connected to the first electrode 130. A second electrode 210 is formed on the second substrate 200 and is opposite to the first electrodes 130. In the present exemplary embodiment, the display apparatus is a liquid crystal display, so the optical layer 300 includes liquid crystal molecules 310 disposed between the first and second substrates 100 and 200.

When operating the liquid crystal display, each thin film transistor 140 is turned on in response to a signal on the corresponding first line 110. Data voltages on the second lines 120 carry image information to the corresponding first electrodes. The second electrode 210 receives a constant common voltage. Consequently, the liquid crystal molecules 310 are subjected to the electric field which depends on the voltage differences between the data voltages and the common voltage. The liquid crystal molecules 310 become rearranged according to the electric field, and this arrangement controls the transmittance of light through the liquid crystal molecules 310 to produce a desired image. Since the liquid crystal molecules 310 are not self-emissive, a separate light source is required to operate the display apparatus. For example, a backlight unit (not shown) can be provided under the first substrate 100.

In the embodiment of FIG. 3B, metal lines including the first and second lines 110 and 120 are formed on the first substrate 100. The metal lines define the matrix of the pixel areas, and the first substrate 100 serves as the array substrate. The second substrate 200 serves as a cover substrate covering the array substrate. Each pixel area includes a first electrode 130 and a thin film transistor 140 that are arranged as in FIG. 3A. In the embodiment of FIG. 3B, the display apparatus is an electroluminance display device including an organic light emitting layer. Therefore, the optical layer 300 includes light emitting layer 320 disposed on the first substrate 100. The light emitting layer 320 includes organic thin films, such as first, second, and third light emitting layers 321, 322, and 323. The second electrode 210 is disposed on the light emitting layer 320.

In operation, the first electrode 130 emits holes, and the second electrode 210 emits electrons. The electrons and holes recombine with each other in the light emitting layer 320, and the recombination causes the light emitting layer 320 to emit light. The first, second and third light emitting layers 321, 322, and 323 may include respective different materials to generate respective different colors. In some embodiments, the first light emitting layer 321 generates red light, the second light emitting layer 322 generates green light, and the third light emitting layer 323 generates blue light. The red, green and blue colors can be mixed in different proportions to display respective different colors on the device.

The invention is not limited to liquid crystal displays or electroluminance displays. The invention covers other types of displays, including inorganic thin film electroluminescent displays (TFEL), plasma displays (PDP), and other types.

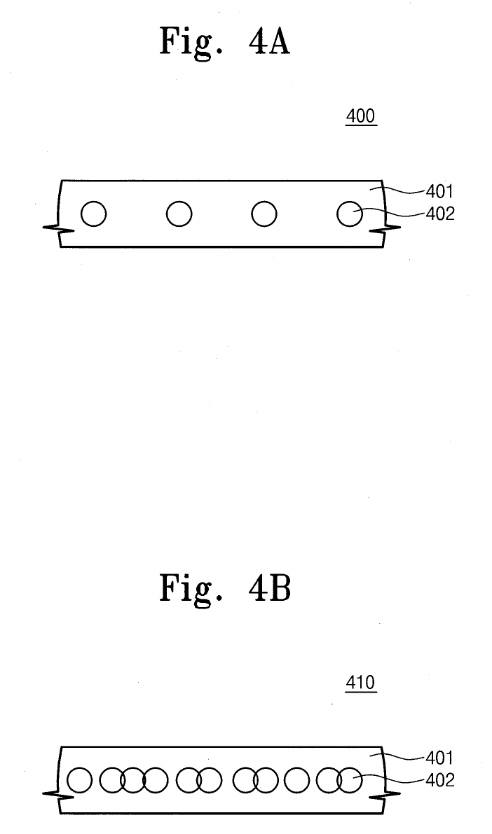

FIGS. 4A and 4B are cross-sectional views showing a joining layer and a buffer layer of FIG. 1, respectively. Referring to FIGS. 4A and 4B, the joining layer 400 and the buffer layer 410 include the same types of materials 401, 402, but in different proportions. Material 401 is a joining agent, and material 402 is a filling agent. The weight concentration of the filling agent 402 in the joining layer 400 is smaller than in the buffer layer 410, and the weight concentration of the joining agent 401 in the joining layer 400 is greater than in the buffer layer 410. For example, in some embodiments, the joining layer 400 has the same weight as the buffer layer 410, and the amount of the filling agent 402 in the joining layer 400 is smaller than in the buffer layer 410.

The joining agent 401 is formed from a glass-frit powder. The glass-frit powder includes various inorganic materials, such as SiO₂, TiO₂, PbO, PbTiO₃, Al₂O₃, etc. The joining agent 401 is formed by irradiating the glass-frit powder with laser light and then hardening the glass-frit. Below, hardened glass-frit is simply called “frit”.

The filling agent 402 includes SiO₂, has a crystalline phase, and has low heat-conductivity and a low thermal expansion coefficient. In some embodiments, the filling agent 402 includes at least one of cordierite, eucryptite, and spodumene.

The frit in the joining agent 401 is capable of adhesively bonding the first substrate 100 with the second substrate 200. Since the frit has a low oxygen transmission rate and a low moisture transmission rate, the frit can protect the optical layer 300 from oxygen and moisture. Also, the frit is durable enough to sustain vacuum-mounting, so that a layer containing the frit can be formed under vacuum to minimize infiltration of oxygen and moisture during fabrication. Unlike the joining agent 401, the filling agent 402 does not act as an adhesive and hence cannot by itself bond the first substrate 100 with the second substrate 200. The filling agent 402 has a different weight concentration in the joining layer 400 than in the buffer layer 410, so the joining layer 400 and the buffer layer 410 have different material properties. Particularly, the amount of the filling agent 402 in the buffer layer 410 is greater than in the joining layer 400, and thus the buffer layer 410 has lower heat conductivity than the joining layer 400.

As shown in FIG. 4A, the joining layer 400 includes isolated particles of the filling agent 402 that are separated from each other by the joining agent 401. As shown in FIG. 4B, the filling agent 402 is present at a higher density in the buffer layer 410 than in the joining layer 400. The buffer layer 410 has a porous structure, and includes clusters of particles of the filling agent 402.

In some embodiments, the weight concentration of the filling agent 402 in the joining layer 400 is in the range of about 10% to about 30%, and in the buffer layer 410 at least about 30%. Preferably, the weight concentration of the filling agent 402 in the buffer layer 410 is in the range from about 50% to about 90%. The large concentration of the filling agent 402 in the buffer layer 410 serves to lower the heat conductivity of the buffer layer 410. The buffer layer 410 and the joining layer 400 are described in detail below in connection with the method of fabrication of the display apparatus.

FIG. 5 is a cross-sectional view showing another exemplary embodiment of a display apparatus according to the present invention.

The display apparatus includes a first substrate 100, a second substrate 200, an optical layer 300, a joining layer 400, and a buffer layer 410. The first and second substrates 100 and 200 face each other, and the optical layer 300 is disposed between the first and second substrates 100 and 200. Depending on the type of the display apparatus, the optical layer 300 may be a liquid crystal layer, or may be a light emitting layer with organic thin films. The joining layer 400 is formed along the periphery of the first and second substrates 100 and 200 to enclose the optical layer 300. The buffer layer 410 includes a first buffer layer 410a and a second buffer layer 410b. The first buffer layer 410a is disposed between the first substrate 100 and the joining layer 400, and the second buffer layer 410b is disposed between the second substrate 200 and the joining layer 400.

The first and second buffer layers 410a and 410b have lower heat conductivities than the joining layer 400. The first buffer layer 410a and the second buffer layer 410b protect respectively the first substrate 100 and the second substrate 200 from the heat generated in the joining layer 400 during fabrication of the display apparatus.

The joining layer 400, the first buffer layer 410a, and the second buffer layer 410b each include a joining agent and a filling agent. The joining agent includes frit. The weight concentration of the filling agent in the joining layer 400 is in the range from about 10% to about 30%, and the weight concentration of the filling agent in the first and second buffer layers 410a and 410b is greater than about 30%. More specifically, if the weight concentration of the filling agent in the first buffer layer 410a is defined as a first weight percentage and the weight concentration of the filling agent in the second buffer layer 410b is defined as a second weight percentage, then the first and second weight percentages are each greater than about 30%. The first and second weight percentages may coincide or may differ from each other.

For instance, if the first and second substrates 100 and 200 are made of the same material to have the same material properties, it is appropriate to set the first and second weight percentages to the same value. If the weight percentage of the filling agent is increased, the heat conductivity of the buffer layer decreases, and the heat generated in the joining layer 400 may be blocked more effectively. Of note, when the first and second substrates 100 and 200 have the same material properties, then the first and second substrates 100 and 200 need the same thermal protection from the heat generated in the joining layer 400. Thus, it is appropriate for the first and second weight percentages to be set to the same value.

Based on similar analysis, if the first and second substrates 100 and 200 are made of different materials to have different properties, it may be appropriate to set the first and second weight percentages to different values.

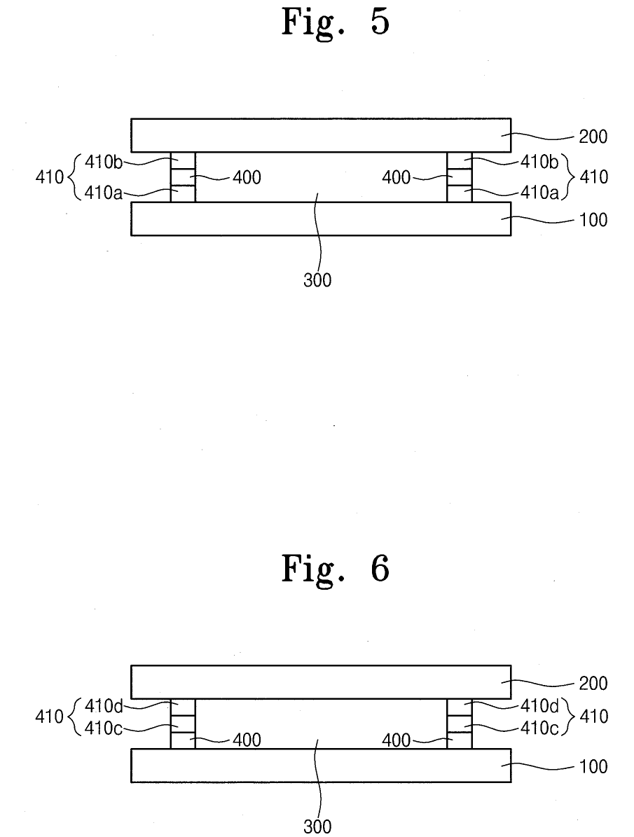

FIG. 6 is a cross-sectional view showing another exemplary embodiment of a display apparatus according to the present invention. The display apparatus of FIG. 6 includes a first substrate 100, a second substrate 200, an optical layer 300, a joining layer 400, and a buffer layer 410. The first and second substrates 100 and 200 face each other, and the optical layer 300 is disposed between the first and second substrates 100 and 200. The joining layer 400 is formed along the periphery of the first and second substrates 100 and 200 to enclose the optical layer 300. The buffer layer 410 includes a third buffer layer 410c and a fourth buffer layer 410d. The third buffer layer 410c and the fourth buffer layer 410d are disposed between the second substrate 200 and the joining layer 400.

The third and fourth buffer layers 410c and 410d have lower heat conductivities than the joining layer 400. The third buffer layer 410c and the fourth buffer layer 410d protect the second substrate 200 from heat generated in the joining layer 400 during the fabrication of the display apparatus.

If the buffer layer 410 had a single-layered structure, the buffer layer 410 could be insufficient for thermal protection of the second substrate 200. In FIG. 6, the buffer layer 410 has a two-layered structure. In some embodiments, the buffer layer 410 has three layers or more as needed for the thermal protection.

The joining layer 400, the third buffer layer 410c, and the fourth buffer layer 410d include the joining agent and the filling agent. The joining agent includes the frit. The weight concentration of the filling agent in the joining layer 400 is in the range from about 10% to about 30%, and in the third and fourth buffer layers 410c and 410d is greater than about 30%. As in the case of the first and second buffer layers 410a and 410b, the weight concentrations of the filling agent in the third and fourth buffer layers 410c, 410d may or may not coincide. For instance, the weight concentration of the filling agent in the third buffer layer 410c, which is positioned adjacent to the joining layer 400, may be much greater than in the fourth buffer layer 410d, which is positioned adjacent to the second substrate 200.

Now one method for fabricating the display apparatus shown in FIG. 1 will be described. The same method can be used for the display apparatuses shown in FIGS. 5 and 6.

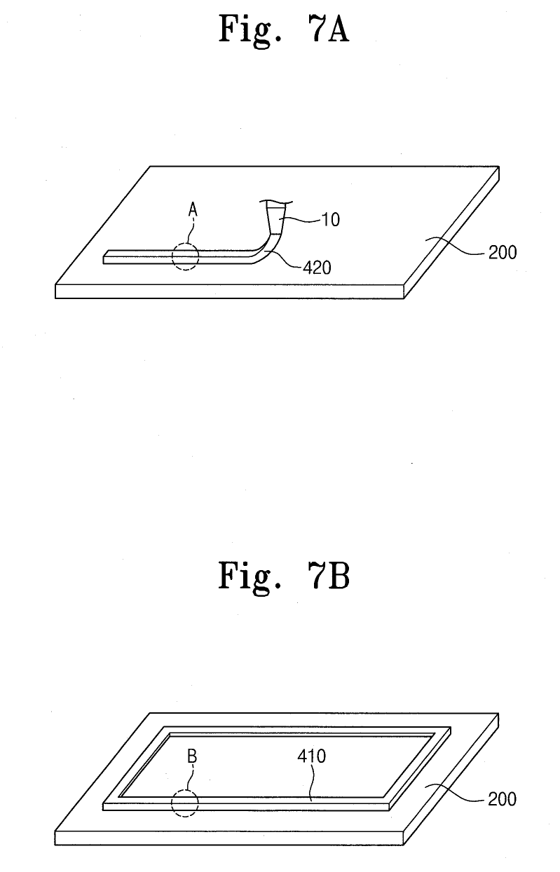

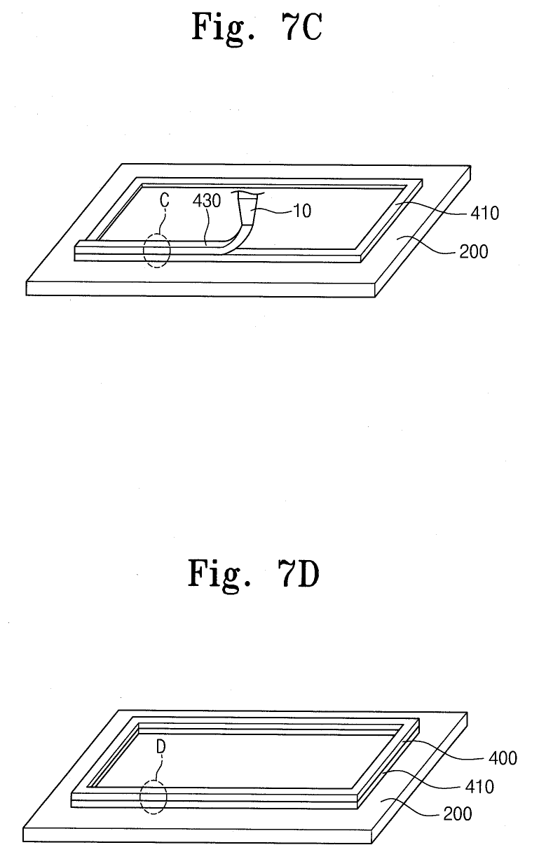

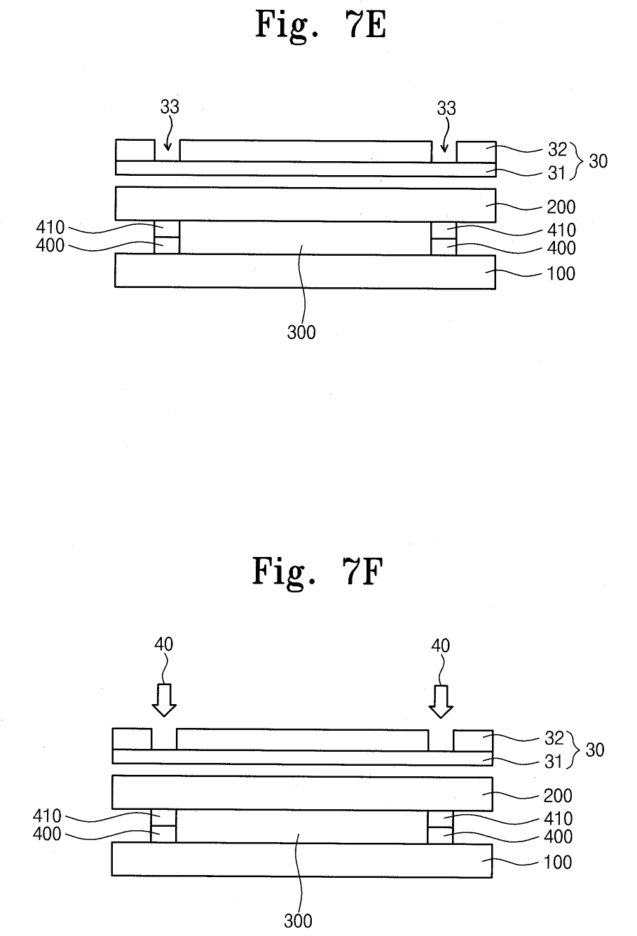

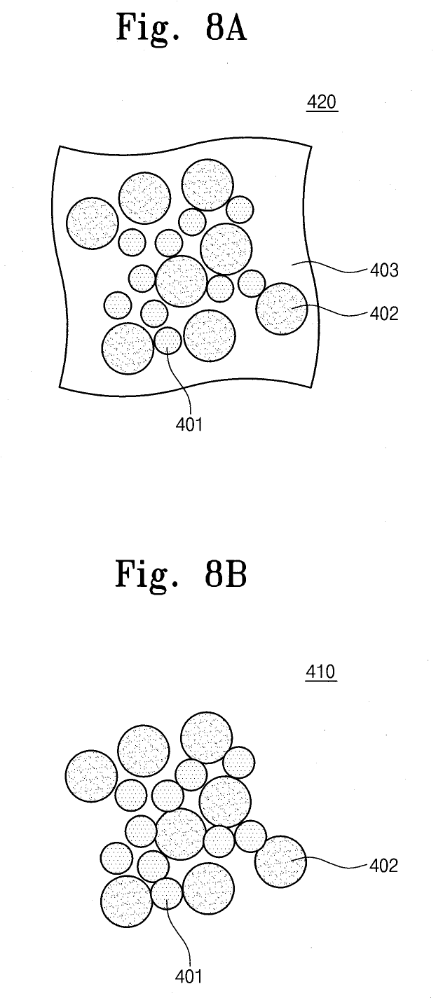

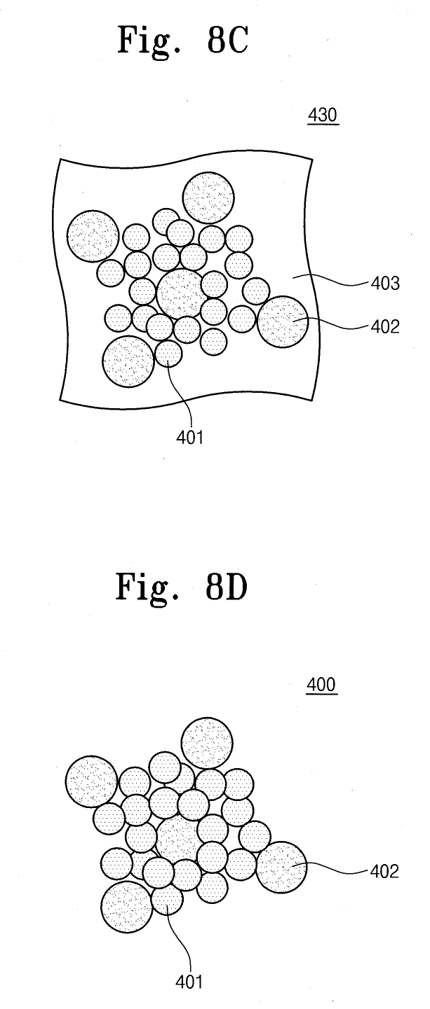

FIGS. 7A to 7F illustrate the display apparatus of FIG. 1 at different stages of fabrication. FIGS. 8A to 8D are enlarged views showing the respective portions ‘A’, ‘B’, ‘C’, and ‘D’ of FIGS. 7A to 7D.

Referring to FIGS. 7A, 7B, the fabrication starts with manufacturing the first and second substrates 100 and 200. The first substrate 100 serves as the array substrate on which the pixel areas are defined, and the second substrate 200 serves as the cover substrate. The first substrate 100 is formed by depositing various layers including photosensitive layers, exposing and developing the photosensitive layers, and etching various layers. These processes form the metal lines on the first substrate 100 to define the pixel areas. Also, the first electrode and the thin film transistor are formed in each pixel area. The optical layer is a light emitting layer formed on the pixel areas. The second electrode is formed on the light emitting layer over the pixel areas.

A first dispenser 10 is positioned above the second substrate 200 at a distance from the second substrate 200. The first dispenser 10 moves along the periphery of the second substrate 200, dispensing a buffer material 420 onto the second substrate's periphery. The buffer material 420 is deposited to form a closed-loop pattern.

As shown in FIG. 8A, the buffer material 420 includes the joining agent 401, the filling agent 402, and a binder 403. The joining agent 401 includes the glass-frit as joining material. The frit includes various inorganic materials such as SiO₂, TiO₂, PbO, PbTiO₃, Al₂O₃, etc. The filling agent 402 includes at least one of cordierite, eucryptite, and spodumene. The binder 403 includes an organic liquid serving as a mediator to mix the joining agent 401 with the filling agent 402.

When preparing the buffer material 420, the joining agent 401 and the filling agent 402 are mixed together in predetermined proportions. In some embodiments, the filling agent 402 has a weight concentration greater than about 30%, preferably from about 50% to about 90%. The mixture of the joining agent 401 and the filling agent 402 is mixed with the binder 403. Since the binder 403 will be evaporated in subsequent processing, the precise content of the binder 403 is not important as long as a sufficient amount of the binder 403 is provided to effectuate mixing of the joining agent 401 with the filling agent 402.

Referring to FIG. 7B, the second substrate 200 is subjected to drying and firing processes. The drying process is performed at a temperature of about 200 degrees, and the firing process is performed at a temperature of about 400 degrees to about 500 degrees. As shown in FIG. 8B, the liquid binder 403 is evaporated during the drying and firing processes to strengthen the adhesion by the joining agent 401.

As a result of the drying and firing processes, the buffer layer 410 forms on the second substrate 200. In the buffer layer 410, the weight ratio of the joining agent 401 to the filling agent 402 is approximately the same as in the buffer material 420 when the buffer material 420 is first prepared.

Referring to FIG. 7C, a second dispenser 20 is positioned above the second substrate 200 at a distance from the second substrate 200. The second dispenser 20 moves along the buffer layer 410 while dispensing a joining material 430 on the buffer layer 410. At the conclusion of this process, the joining material 430 is overlapped with the buffer layer 410 in a plan view, and the buffer layer 410 and the joining material 430 are substantially placed at the same position in a plan view, and the joining material 430 has a closed-loop pattern. When a size of the joining material 430 is bigger than a size of the buffer layer 410 in a plan view, the joining material 430 may be touched with the second substrate, so heat generated during fabrication of the display may be conducted to the second substrate 200. Therefore, it is desirable that the buffer layer 410 and the joining material 430 are substantially placed at the same position in a plan view.

As shown in FIG. 8C, the joining material 430 includes the joining agent 401, the filling agent 402, and the binder 403. The materials 401, 402, 403 can be the same materials as in the buffer material 420. In particular, in some embodiments the joining agent 401 includes the frit, the filling agent 402 includes at least one of cordierite, eucryptite, and spodumene, and the binder 403 includes the organic liquid.

The joining material 430 can be prepared using substantially the same processes as the buffer material 420. Thus, in some embodiments, the joining agent 401 and the filling agent 402 are mixed with each other in predetermined proportions. The weight concentration of the joining agent 401 is greater than about 70%, and weight concentration of the filling agent 402 is smaller than about 30%. The mixture of the joining agent 401 and the filling agent 402 is then mixed with the binder 403.

Referring to FIG. 7D, the second substrate 200 is subjected to the drying and firing processes. The drying process is performed at a temperature of about 200 degrees, and the firing process is performed at a temperature in the range from about 400 degrees to about 500 degrees. As shown in FIG. 8D, the liquid binder 403 evaporates during the drying and firing processes to strengthen the adhesion by the joining agent 401. As a result of the drying and firing processes, the joining layer 400 is formed on the buffer layer 410. In the joining layer 400, the weight ratio of the joining agent 401 to the filling agent 402 is approximately the same as in the joining material 430 when the joining material 430 is first prepared.

Comparison of FIGS. 8B and 8D illustrates that in the joining layer 400 (FIG. 8D) the weight concentration of the joining agent 401 is higher, and hence particles of the joining agent 401 bond together very well. In contrast, in the buffer layer 410 (FIG. 8B), the weight concentration of the joining agent 401 is lower, so that different portions of the joining agent 401 can be separated from each other.

Referring to FIG. 7E, the first and second substrates 100 and 200 are arranged to face each other, and a mask 30 is disposed on the second substrate 200. The mask 30 includes a transparent insulating layer 31 and an opaque metallic layer 32. The transparent insulating layer 31 includes quartz or sodalime, and the opaque metallic layer 32 includes copper. The opaque metallic layer 32 is provided with an opening 33 formed therethrough, and the mask 30 is arranged to align the opening 33 above the joining layer 400 and the buffer layer 410.

Referring to FIG. 7F, a laser beam 40 is emitted onto the second substrate 200 from above the mask 30. The laser beam 40 is blocked by the opaque metallic layer 32 except at the opening 33, and is incident into the second substrate 200 through the opening 33. As a result, the laser beam 40 passes to the buffer layer 410 and the joining layer 400 and is absorbed by the joining agent 401 in the buffer layer 410 and the joining layer 400. The filling agent 402 does not absorb the laser light 40. When the frit in the joining agent 401 absorbs the laser light 40, the frit becomes fluid and flows to the first and second substrates 100 and 200. Then the laser beam 40 is turned off, and consequently the frit hardens to bond the first and second substrates 100 and 200 to each other. The buffer layer 410 protects the second substrate 200 from the heat generated in the joining layer 400 by the laser beam 40.

If the buffer layer 410 is omitted, then the joining layer 400 contacts the second substrate 200. In this case, the heat generated in the joining layer 400 by the laser beam 40 is transmitted directly to the second substrate 200. When the laser beam 40 moves along the periphery of the second substrate 200 while irradiating the second substrate 200, the portions of the joining layer 400 which are exposed to the laser beam 40 are rapidly cooled after the exposure. Thus, the exposed portions of the second substrate 200 experience rapid heating and cooling, and the attendant thermal expansion and shrinkage may damage the second substrate 200.

The buffer layer 410 is disposed between the joining layer 400 and the second substrate 200 to smoothen the temperature changes in the second substrate 200. As a result, the second substrate 200 is less likely to be damaged by the thermal expansion and shrinkage. Of note, the buffer layer 410 includes a large amount of filling agent 402, and the filling agent 402 has low heat conductivity. The heat conductivity of the buffer layer 410 can therefore be reduced by increasing the content of the filling agent 402. The buffer layer 410 therefore protects the second substrate 200 from the heat in the joining layer 400.

The thermal expansion coefficients of the first and second substrates 100 and 200 depend on the materials used to form the two substrates. If the thermal expansion coefficient of the second substrate 200 is small, then the temperature gradients in the second substrate 200 during the exposure to the laser beam 40 will be small, thereby preventing the damage of the second substrate 200 due to the expansion and the shrinkage.

In the electroluminance display device, the first and second substrates 100 and 200 may have different materials. For instance, the first substrate 100 may include a glass developed by Samsung Corning Co., Ltd., and distributed under the trade name of E2K™ (Eagle 2000), and the second substrate 200 may include a sodalime glass. The E2K glass and the sodalime glass include silica (SiO₂) as the main component. The E2K glass is obtained by removing alkali metals and alkali-earth metals from the sodalime glass. Thus, the sodalime glass includes oxides of alkali metals or alkali-earth metals, such as Na₂O, CaO, MgO, and such oxides are removed in manufacturing the E2K glass. Therefore, the E2K glass and the sodalime glass have different properties. For example, the thermal expansion coefficient of the E2K glass is lower by ⅓ than the thermal expansion coefficient of the sodalime glass.

Since the E2K glass is more expensive than the sodalime glass, the manufacturing cost may be reduced by using substrates made using the sodalime glass. However, the sodalime glass has a greater thermal expansion coefficient than the E2K glass, and hence the sodalime glass is more easily damaged by the thermal cycling (expansion and shrinkage) during the application of the laser beam 40. Therefore, if the display device uses a substrate made using sodalime glass or other materials with high thermal expansion coefficients, it is particularly desirable to use the buffer layer 410 between the joining layer 400 and the substrate to protect the substrate from being damaged by thermal cycling.

During manufacturing, the first substrate 100 is subjected to thin film processes needed to form the metal lines and the thin film transistors. Therefore, in some embodiments, the first substrate 100 is formed using the E2K glass. Since the second substrate 200 only serves to cover the first substrate 100, the second substrate 200 can be formed using the sodalime glass with the buffer layer 410. In other embodiments, both the first and second substrates 100 and 200 are formed using the sodalime glass, with one buffer layer 410 disposed between the first substrate 100 and the joining layer 400, and another buffer layer 410 between the second substrate 200 and the joining layer 400.

Now the weight concentrations of the joining agent 401 and the filling agent 402 will be described in detail.

As mentioned above, the filling agent 402 does not provide adhesion between the first and second substrates 100 and 200. The filling agent 402 has a weight concentration of at most about 30% in the joining layer 400. The relatively small concentration is chosen because the filling agent 402 does not absorb the laser light 40, and also the temperature needed to harden the fluid frit increases if the weight concentration of the filling agent 402 is above about 30%. The higher temperature requirement may be met by increasing the power consumption in generating the laser beam 40, and/or reducing the motion speed of the laser beam 40 along the substrate periphery and thus increasing the manufacturing time, all of which are undesirable. Hence, in some embodiments the weight concentration of the filling agent 402 in the joining layer 400 is at most about 30% and greater than about 10%.

In the buffer layer 410, the weight concentration of the filling agent 402 is greater than about 30%. If the weight concentration of the filling agent 402 is about 50% or more, then the amount of the joining agent 401 may be insufficient to fill spaces between the filling agent's particles. As a result, unfilled pores form in the buffer layer 401, and thus the buffer layer 401 has a porous structure.

The pores help block the heat transmission from the joining layer 400 to the second substrate 200 immediately after the irradiation by the laser light 40. During a period of time immediately following the irradiation, despite the low content of the frit in the buffer layer 410, the pores become filled with the frit diffused into the buffer layer 410 from the joining layer 400 to seal the space between the first and second substrates 100 and 200.

The heat-blocking effect by the buffer layer 410 is enhanced if the proportion of the filling agent 402 increases and the proportion of the joining agent 401 decreases. However, in some embodiments, the concentration of the joining agent 401 in the buffer layer 410 is at least 10 weight percent since the adhesive bond between the filling agent's particles is weakened if the concentration of the joining agent 401 is too small.

The present invention is not limited to the embodiments described above, but includes other embodiments as defined by the appended claims.

What is claimed is:

1. A display apparatus comprising:
a first substrate on which pixel areas are defined;
a second substrate facing the first substrate;
a joining layer interposed between the first and second substrates, to bond the first and second substrates to each other; and
a buffer layer interposed between the joining layer and at least one of the first and second substrates, the buffer layer having lower heat conductivity than the joining layer.

2. The display apparatus of claim 1, wherein the buffer layer is interposed between the second substrate and the joining layer and comprises sodalime glass.

3. The display apparatus of claim 1, wherein the buffer layer is overlapped with the joining layer when viewed in a plan view, and the buffer layer and the joining layer are placed at the same position in a plan view.

4. The display apparatus of claim 1, wherein each of the joining layer and the buffer layer comprises a joining agent and a filling agent.

5. The display apparatus of claim 4, wherein a weight concentration of the filling agent in the joining layer is smaller than a weight concentration of the filling agent in the buffer layer.

6. The display apparatus of claim 4, wherein the joining agent comprises frit.

7. The display apparatus of claim 6, wherein the filling agent comprises at least one of a group consisting of cordierite, eucryptite, and spodumene.

8. The display apparatus of claim 7, wherein a weight concentration of the filling agent in the joining layer is in a range from about 10% to about 30%, and a weight concentration of the filling agent in the buffer layer is greater than about 30%.

9. The display apparatus of claim 8, wherein the weight concentration of the filling agent in the buffer layer is in a range from about 50% to about 90%.

10. The display apparatus of claim 1, further comprising a light emitting layer interposed between the first and second substrates.

11. A method of fabricating a display apparatus, the method comprising:
providing a first substrate on which pixel areas are defined, and a second substrate;
forming a buffer layer on at least one of the first and second substrates;
forming a joining layer on the buffer layer, the joining layer having a higher heat conductivity than the buffer layer;
bonding the first and second substrates to each other, with the buffer layer and the joining layer being between the first and second substrates.

12. The method of claim 11, wherein the buffer layer and the joining layer are formed on the second substrate, and the second substrate comprises sodalime glass.

13. The method of claim 11, wherein forming the buffer layer comprises:
depositing a buffer material on said at least one of the first and second substrates;
drying the buffer material; and
firing the buffer material, the buffer material providing the buffer layer.

14. The method of claim 13, wherein forming the joining layer comprises:
depositing a joining material on the buffer layer to allow the joining material and the buffer layer to be placed at the same position in a plan view; drying the joining material; and
firing the joining material.

15. The method of claim 14, wherein each of the joining material and the buffer material comprises a joining agent, a filling agent, and a binder.

16. The method of claim 15, wherein a weight ratio of the filling agent to the joining agent in the joining material is smaller than a weight ratio of the filling agent to the joining agent in the buffer material.

17. The method of claim 15, wherein the joining agent comprises a frit.

18. The method of claim 17, wherein the filling agent comprises at least one of a group consisting of cordierite, euryptite, and spodumene.

19. The method of claim 18, wherein a ratio of a weight of the filling agent to a combined weight of the filling agent and the joining agent is in a range from about 10% to about 30% in the joining material, and greater than about 30% in the buffer material.

20. The method of claim 19, wherein the ratio of the weight of the filling agent to the combined weight of the filling agent and the joining agent is in a range from about 50% to about 90% in the buffer material.
